(19) United States
(12) Patent Application Publication
(10) Pub. No.: US 2026/0081397 A1
(43) Pub. Date: Mar. 19, 2026

(54) APPARATUS FOR AND METHOD OF CONTROL FOR SPECTRUM SEPARATION

(71) Applicant: Cymer, LLC, San Diego, CA (US)

(72) Inventor: Ge Song, San Diego, CA (US)

(21) Appl. No.: 18/867,717

(22) PCT Filed: Aug. 2, 2023
(86) PCT No.: PCT/US2023/029291

§ 371 Date: Nov. 20, 2024

Related U.S. Application Data
(60) Provisional application No. 63/395,368, filed on Aug. 5, 2022.

(51) Int. Cl. H01S 3/104; G03F 7/00; G03F 7/20; H01S 3/23

(52) U.S. Cl. CPC H01S 3/104; G03F 7/2004; G03F 7/70025; G03F 7/70041; G03F 7/705; G03F 7/70508; G03F 7/70575; H01S 3/2308

(57) ABSTRACT

Apparatus for and methods of rapidly achieving a target peak wavelength separation in a system for producing laser radiation at more than one wavelength in which one or more actuators control wavelength in response to being supplied with a waveform. The characteristics of the waveform are determined using a model reference control system.

### CROSS-REFERENCE TO RELATED APPLICATIONS

This application is a United States National Phase Patent Application of International Patent Application Number PCT/US2023/029291, filed on Aug. 2, 2023, which claims priority to U.S. application 63/395,368 which was filed on 5 Aug. 2022, each of which are incorporated herein in their entireties by reference.

### FIELD

The present disclosure relates to laser systems such as excimer lasers that produce light and systems and methods for controlling a center wavelength of such lasers.

### BACKGROUND

A lithographic apparatus applies a desired pattern onto a substrate such as a wafer of semiconductor material, usually onto a target portion of the substrate. A patterning device, which may be a mask or a reticle, may be used to generate a circuit pattern to be formed on an individual layer of the wafer. Transfer of the pattern is typically accomplished by imaging onto a layer of radiation-sensitive material (resist) provided on the substrate. In general, a single substrate will contain adjacent target portions that are successively patterned.

Lithographic apparatus includes so-called steppers, in which each target portion is irradiated by exposing an entire pattern onto the target portion at one time, and so-called scanners, in which each target portion is irradiated by scanning the pattern through a radiation beam in a given direction (the “scanning” direction) while synchronously scanning the substrate parallel or anti-parallel to this direction. It is also possible to transfer the pattern from the patterning device to the substrate by imprinting the pattern onto the substrate.

The light source used to illuminate the pattern and project it onto the substrate can be of any one of a number of configurations. Deep ultraviolet (DUV) excimer lasers commonly used in lithography systems include the krypton fluoride (KrF) laser at 248 nm wavelength and the argon fluoride (ArF) laser at 193 nm wavelength.

The lithographic apparatus may operate at a single wavelength in what may be referred to as a single-color mode. For some applications, however, it is desired to have the ability to change wavelength, that is, to operate in a multi-color mode to control the depth of focus (DoF). For example, in the fabrication of 3D NAND memory, structures resembling NAND gates are stacked on top of each other, extending the fabrication in a third dimension orthogonal to the x-y plane of the 2D substrate. The transition from 2D to 3D NAND architecture requires significant changes in manufacturing processes.

These considerations lead to a need for a greater DoF. Lithography DoF is determined by the relationship DoF=±m2 λ/(NA)² where λ is the wavelength of the illuminating light, NA is the numerical aperture, and m2 is a practical factor depending on the resist process. Due to greater DoF requirements in 3D NAND lithography, sometimes more than one exposure pass is made over a wafer using a different laser wavelength for each pass.

Multifocal imaging (MFI) uses multiple focus levels (e.g., via multiple wavelengths) to effectively increase DoF for a given NA of the objective lens. This technique can be tuned specifically to provide the required amount of wavelength separation (peak separation) for a specific DoF need. This enables the imaging NA, and therefore exposure latitude (process window), to be increased while the DoF can be optimized by MFI in accordance with production layer needs.

In addition, the materials making up the lenses that focus the laser radiation are dispersive, so different wavelengths come to focus at different depths. This is another reason why it may be desirable to have the ability to change wavelengths.

To accomplish MFI an element in the optical train is moved back-and-forth between two angular positions with the source (1) generating light having the first wavelength when the element is in one of the positions and (2) generating light having the second wavelength when the element is in the other of the positions. The element is moved under the control of a command voltage produced by an electro-actuatable element (EAE), e.g., a piezoelectric transducer (PZT), a stepper motor, a valve, a pressure-controlled device, an electromagnet, a solenoid, another type of piezoelectric device, a linear motor, a hydraulic actuator, a voice coil, and/or any other type of device capable of generating a motive force under the command of a control signal.

In a single-color mode, two actuators, i.e., a stepper motor and a PZT, work in conjunction with one another to stabilize the center wavelength. In operation, the stepper motor has limited resolution, and as such, the PZT is used as the primary actuator. However, in a two-color mode, wavelength stability is based on a central or peak wavelength, i.e., a mean of two alternating spectra, and in this mode, the PZT is tasked with the production of the waveform that generates the alternating wavelengths.

As a specific example, in an application of generating DUV light at two different wavelengths, the reference wavelength has two set points during exposure, that is, a first set point at a first wavelength and a second set point at a second wavelength. The reference wavelength will then be modulated between these two set points. Every wavelength target change requires a predetermined settling time.

A DUV light source includes systems for controlling the wavelength of the DUV light. Typically, these wavelength control systems include feed-forward compensators to promote wavelength stability. The feed-forward compensator compensates for commanded changes in the wavelength target, that is, wavelength change events. When such an event occurs, a settling time must be allowed for the system to settle stably to the new wavelength.

Typically, an MFI algorithm presumes the laser will be operated in MFI mode only at (or substantially near) a specific repetition rate, e.g., 6 kHz, and so calibrates and optimizes the base waveform for the PZT dither for performance at this single operation point. This base waveform is then modified burst-to-burst using an iterative learning control (ILC) algorithm to compensate for drifts and operation (reasonably) outside the anticipated operation points.

Desired peak separation performance is obtained by using an MFI algorithm which depends on an accurate knowledge of PZT calibration results. There is, however, uncertainty (nonlinearity) in the performance of the PZT at repetition rates at the PZT resonance frequency or harmonics of that frequency. As a result, the calibrated gain of the PZT voltage is not dependable at these frequencies. The sequence of using an accurate calibrated result in the existing MFI control algorithm results in a slow transient response with a large overshoot when the laser fires at a repetition rate around (2*PZT resonance) Hz. In fact, it can take around one hundred pulses for the peak separation, variation in which is used as a measure of system stability, to converge to a desired value. This behavior essentially precludes the use of repetition rates at or near PZT resonances and their harmonics.

It is in this context that the need for the subject matter disclosed herein arises.

### SUMMARY

The following presents a succinct summary of one or more embodiments in order to provide a basic understanding of the embodiments. This summary is not an extensive overview of all contemplated embodiments. It is not intended to identify any elements of embodiments as being key or critical elements nor delineate the scope of any or all embodiments. Its sole purpose is to present some concepts of one or more embodiments in a concise form as a prelude to the more detailed description that is presented later.

According to one aspect of an embodiment there is disclosed a laser system comprising a source of laser radiation, the laser radiation being fired in one or more bursts, each burst being made up of a plurality of pulses, a wavelength controller arranged to receive the pulses and to control a primary wavelength of some of the pulses toward a first value and to control a primary wavelength of others of the pulses toward a second value different from the first value by a target primary wavelength separation amount, the wavelength controller including at least one actuator operating in response to a control signal to effect wavelength control of the pulses, and a model reference adaptive control system adapted to generate the control signal based at least in part on a measured primary wavelength separation amount, to cause the wavelength controller to achieve the target primary wavelength separation amount.

The source of laser radiation may be an excimer laser. The actuator may comprise a piezoelectric transducer. The wavelength controller may be a line narrowing module. The wavelength controller may be a line narrowing module including an optical element mechanically coupled to the at least one actuator. The at least one actuator may comprise a piezoelectric transducer.

According to another aspect of an embodiment there is disclosed a multifocal imaging photolithography system generating first wavelength pulses of deep ultraviolet radiation having a first primary wavelength and second wavelength pulses of deep ultraviolet radiation having a second primary wavelength differing from the first primary wavelength by a primary separation amount, the multifocal imaging photolithography system comprising a wavelength controller arranged to receive input pulses of deep ultraviolet radiation and to control a primary wavelength of a first subset of the pulses to obtain the first wavelength pulses and to control a primary wavelength of a second subset of the input pulses to obtain the second wavelength pulses in response to a control signal and a model reference adaptive control system adapted to generate the control signal based at least in part on a measured primary separation of wavelengths of the first wavelength pulses and the second wavelength pulses to cause the wavelength controller to achieve and maintain a target primary separation amount.

The source of laser radiation may be an excimer laser. The wavelength controller may comprise an electro-actuable component. The wavelength controller may be a line narrowing module. The line narrowing module may comprise an electro-actuable component. The electro-actuable component may comprise a piezoelectric transducer.

According to another aspect of an embodiment there is disclosed a system for controlling a wavelength of laser radiation being fired in one or more bursts, each burst being made up of a plurality of pulses, the system comprising a wavelength controller arranged to receive the pulses and to control a primary wavelength of some of the pulses towards a first value and to control a primary wavelength of others of the pulses towards a second value different from the first value by a target primary wavelength separation amount, the wavelength controller including at least one actuator operating in response to a control signal to effect wavelength control of the pulses; and a model reference adaptive control system adapted to generate the control signal based at least in part on a measured primary separation amount to cause the wavelength controller to achieve the target primary separation amount.

The actuator may comprise a piezoelectric transducer. The wavelength controller may be a line narrowing module. The wavelength controller may be a line narrowing module including an optical element mechanically coupled to the actuator. The actuator may comprise a piezoelectric transducer.

Each burst may comprise the plurality of pulses fired at a repetition rate, and the model reference adaptive control system may be adapted to generate the control signal based at least in part on a measured primary wavelength separation amount to cause the wavelength controller to achieve the target primary separation amount even when the repetition rate is in a critical range at which operation of the electro-actuable component would otherwise be unstable. The critical range may be +/−10% of a resonance frequency of the electro-actuable component or a harmonic of the resonance frequency of the electro-actuable component. The electro-actuable component may comprise a piezoelectric transducer.

According to another aspect of an embodiment there is disclosed a method of controlling a multifocal imaging photolithography system to generate first wavelength pulses of radiation having a first primary wavelength and second wavelength pulses of radiation having a second primary wavelength differing from the first primary wavelength by a primary separation amount, the method comprising generating input pulses of laser radiation, using a wavelength controller to control a primary wavelength of a first subset of the input pulses to obtain the first wavelength pulses and to control a primary wavelength of a second subset of the input pulses to obtain the second wavelength pulses in response to a control signal, comparing a primary wavelength separation of the first wavelength pulses and the second wavelength pulses with a primary wavelength separation obtained from a reference model controlled by a reference signal to obtain an error signal, and modifying one or more parameters of the control signal at least partially on the basis of the error signal to cause a response of the wavelength controller to the control signal to track a response of the reference model to the reference signal.

Generating input pulses of laser radiation may be performed using an excimer laser. Using a wavelength controller may comprise using a line narrowing module.

Further features and exemplary aspects of the embodiments, as well as the structure and operation of various embodiments, are described in detail below with reference to the accompanying drawings. It is noted that the scope of all possible embodiments is not limited to the specific embodiments described herein. Such specific embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the embodiments and, together with the description, further serve to explain the principles of the embodiments and to enable a person skilled in the relevant art(s) to make and use the embodiments.

FIGS. 1A, 1B and 1C provide a schematic illustration of a lithographic apparatus, according to an embodiment.

FIG. 2A is a schematic illustration of a light source apparatus, according to an embodiment.

FIG. 2B is a schematic illustration of a spectral feature actuation system according to an embodiment.

FIG. 2C is a schematic cross-sectional illustration of a line narrowing module according to an embodiment.

FIGS. 3A-3C are diagrams of a laser burst made up of laser pulses illustrating certain principles underlying operation of an aspect of an embodiment.

FIG. 4 is a conceptual schematic of a photolithography system according to an aspect of an embodiment.

FIG. 5 is a graph of the single-peaked optical spectrum of laser radiation according to an aspect of an embodiment.

FIG. 6 is a graph of the double-peaked optical spectrum of laser radiation according to an aspect of an embodiment.

FIG. 7 shows an example of an average optical spectrum at a wafer according to an aspect of an embodiment.

FIG. 8 is a diagram of a model reference adaptive control system for controlling the LNM for MFI according to an aspect of an embodiment.

FIG. 9 is a flow chart for a process for operation of a model reference adaptive control system for controlling the LNM for MFI according to an aspect of an embodiment.

FIG. 10 is a functional block diagram of a computer control system according to an aspect of an embodiment.

The features and exemplary aspects of the embodiments will become more apparent from the detailed description set forth below when taken in conjunction with the drawings. In the drawings, like reference numbers generally indicate identical, functionally similar, and/or structurally similar elements. Unless otherwise indicated, the drawings should not be interpreted as to-scale drawings.

### DETAILED DESCRIPTION

The embodiment(s) described, and references in the specification to “one embodiment,” “an embodiment,” “an exemplary embodiment,” “an example embodiment,” etc., indicate that the embodiments described may include a particular feature, structure, or characteristic, but not every embodiment necessarily includes the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms may be used herein for ease of description to describe one element or feature's relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” or “approximately” as used herein indicates the value of a given quantity that can vary based on a particular technology. Based on the particular technology, the term “about” or “substantially” or “approximately” can indicate a value of a given quantity that varies within, for example, 1-15% of the value (e.g., ±1%, ±2%, ±5%, ±10%, or ±15% of the value).

Embodiments of the disclosure may be implemented in hardware, firmware, software, or any combination thereof. Embodiments of the disclosure may also be implemented as instructions stored on a tangible machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure may be implemented.

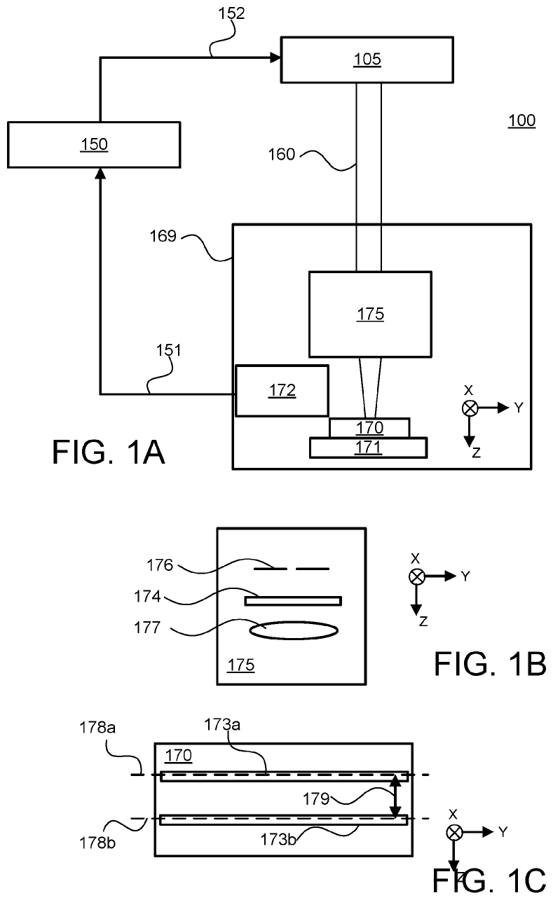

Referring to FIG. 1A, a photolithography system 100 includes an optical (or light) source 105 that provides a light beam 160 to a lithography exposure apparatus 169, which processes a wafer 170 received by a wafer holder or stage 171. The light beam 160 is a pulsed light beam that includes pulses of light separated from each other in time. The lithography exposure apparatus 169 includes a projection optical system 175 through which the light beam 160 passes prior to reaching the wafer 170, and a metrology system 172. The metrology system 172 may include, for example, a camera or other device that is able to capture an image of the wafer 170 and/or the light beam 160 at the wafer 170, or an optical detector that is able to capture data that describes characteristics of the light beam 160, such as intensity of the light beam 160 at the wafer 170 in the x-y plane. The lithography exposure apparatus 169 can be a liquid immersion system or a dry system. The photolithography system 100 also may include a control system 150 to control the light source 105 and/or the lithography exposure apparatus 169.

Microelectronic features are formed on the wafer 170 by, for example, exposing a layer of radiation-sensitive photoresist material on the wafer 170 with the light beam 160. Referring also to FIG. 1B, the projection optical system 175 includes a slit 176, a mask 174, and a projection objective, which includes a lens 177. The light beam 160 enters the optical system 175 and impinges on the slit 176, and at least some of the beam 160 passes through the slit 176. In the example of FIGS. 1A and 1B, the slit 176 is rectangular and shapes the light beam 160 into an elongated rectangular shaped light beam. A pattern is formed on the mask 174, and the pattern determines which portions of the shaped light beam are transmitted by the mask 174 and which are blocked by the mask 174. The design of the pattern is determined by the specific microelectronic circuit design that is to be formed on the wafer 170.

The shaped light beam interacts with the mask 174. The portions of the shaped light beam that are transmitted by the mask 174 pass through (and may be focused by) the projection lens 177 and expose the wafer 170. The portions of the shaped light beam that are transmitted by the mask 174 form an aerial image in the x-y plane in the wafer 170. The aerial image is the intensity pattern formed by the light that reaches the wafer 170 after interacting with the mask 174.

The system 100 is able to form a plurality of aerial images during a single exposure pass, with each of the aerial images being at a spatially distinct location along the z axis in the wafer 170. Referring also to FIG. 1C, which shows a cross-sectional view of the wafer 170 in the y-z plane, the projection optical system 175 forms two aerial images 173a, 173b at different planes along the z axis in a single exposure pass. As discussed in greater detail below, each of the aerial images 173a, 173b is formed from light having a different primary wavelength.

The location of the aerial image along the z axis depends on the characteristics of the optical system 175 (including the projection lens 177 and the mask 174) and the wavelength of the light beam 160. The focal position of the lens 177 depends on the wavelength of the light incident on the lens 177. Thus, varying or otherwise controlling the wavelength of the light beam 160 allows the position of the aerial image to be controlled. By providing pulses having different primary wavelengths of light during a single exposure pass, a plurality (two or more) of aerial images, which are each at a different location along the z axis, may be formed in a single exposure pass without moving the optical system 175 (or any components of the optical system 175) and the wafer 170 relative to each other along the z axis.

In the example of FIG. 1B, light passing through the mask 174 is focused to a focal plane by the projection lens 177. The focal plane of the projection lens 177 is between the projection lens 177 and the wafer stage 171, with the position of the focal plane along the z axis depending on the properties of the optical system 175 and the wavelength of the light beam 160. The aerial images 173a, 173b are formed from light having different wavelengths, thus the aerial images 173a, 173b are at different locations in the wafer 170. The aerial images 173a, 173b are separated from each other along the z axis by a separation distance 179. The separation distance 179 depends on the difference between the wavelength of the light that forms the aerial image 173a and the wavelength of the light that forms the aerial image 173b.

The separation distance 179 is formed due to the ability to control the primary wavelengths in the pulses that pass through the mask 174 during the exposure pass. Moreover, the aerial images 173a and 173b are both present at the wafer 170 during the same exposure pass. In other words, the system 100 does not require that the aerial image 173a be formed in a first exposure pass and the aerial image 173b be formed in a second, subsequent exposure pass.

The light in the first aerial image 173a interacts with the wafer at a depth 178a, and the light in the second aerial image 173b interacts with the wafer at a depth 178b. These interactions may form electronic features or other physical characteristics, such as openings or holes, on the wafer 170. Because the aerial images 173a and 173b are formed at positions that are displaced along the z axis, forming the aerial images 173a and 173b may be used as part of a process to fabricate three-dimensional features on the wafer 170. For example, the aerial image 173a may be used to form a periphery region, and the aerial image 173b may be used to form a channel, trench, or recess that is at a different location along the z axis. As such, the techniques discussed herein may be used to form a three-dimensional semiconductor component, such as a three-dimensional NAND flash memory component.

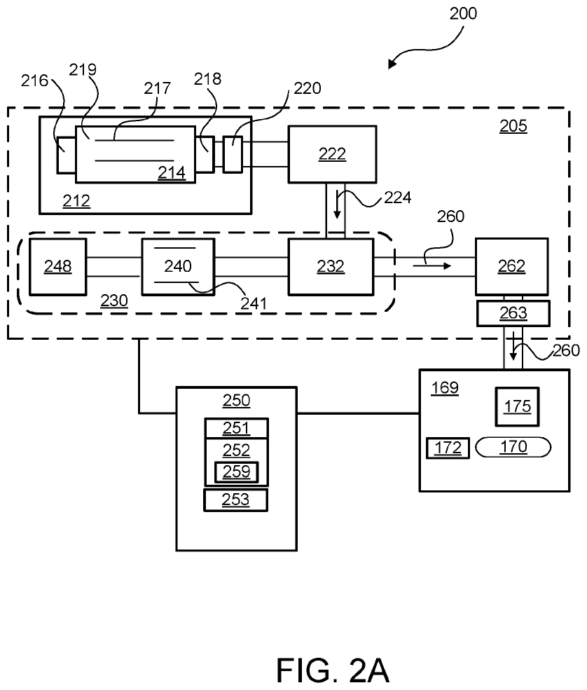

Before discussing additional details related to forming multiple aerial images in a single exposure pass, example implementations of the light source 105 and the photolithography system 100 are described with respect to FIGS. 2A-2C, 3A-3C, and 4.

Referring to FIG. 2A, a block diagram of a photolithography system 200 is shown. The system 200 is an example of an implementation of the system 100 (FIG. 1A). For example, in the photolithography system 200, an optical source 205 is used as the optical source 105 (FIG. 1A). The optical source 205 produces a pulsed light beam 260, which is provided to the lithography exposure apparatus 169. The optical source 205 may be, for example, an excimer optical source that outputs the pulsed light beam 260 (which may be a laser beam). As the pulsed light beam 260 enters the lithography exposure apparatus 169, it is directed through the projection optical system 175 and projected onto the wafer 170. In this way, one or more microelectronic features are patterned onto a photoresist on the wafer 170 that is then developed and cleaned prior to subsequent process steps, and the process repeats. The photolithography system 200 also includes a control system 250, which, in the example of FIG. 2A, is connected to components of the optical source 205 as well as to the lithography exposure apparatus 169 to control various operations of the system 200. The control system 250 is an example of an implementation of the control system 150 of FIG. 1A.

In the example shown in FIG. 2A, the optical source 205 is a two-stage laser system that includes a master oscillator (MO) 212 that provides a seed light beam 224 to a power amplifier (PA) 230. The MO 212 and the PA 230 may be considered to be subsystems of the optical source 205 or systems that are part of the optical source 205. The power amplifier 230 receives the seed light beam 224 from the master oscillator 212 and amplifies the seed light beam 224 to generate the light beam 260 for use in the lithography exposure apparatus 169. For example, the master oscillator 212 may emit a pulsed seed light beam, with seed pulse energies of approximately 1 millijoule (mJ) per pulse, and these seed pulses may be amplified by the power amplifier 230 to about 10 to 15 mJ.

The master oscillator 212 includes a discharge chamber 240 having two elongated electrodes 217, a gain medium 219 that is a gas mixture, and a fan for circulating gas between the electrodes 217. A resonator is formed between a line narrowing module (LNM) 216 on one side of the discharge chamber 240 and an output coupler 218 on a second side of the discharge chamber 240. The LNM 216 may include a diffractive optic such as a grating that finely tunes the spectral output of the discharge chamber 240. FIGS. 2B and 2C provide additional detail about the LNM 216.

FIG. 2B is a block diagram of an example of an implementation of a spectral feature selection module 258. The spectral feature selection module 258 couples to light that propagates in the optical source 205. In some implementations (such as shown in FIG. 2B), the spectral feature selection module 258 receives the light from the chamber 214 of the master oscillator 212 to enable fine tuning of the spectral features such as wavelength and bandwidth within the master oscillator 212.

The spectral feature selection module 258 may include a control module such as a spectral feature control module 254 that includes electronics in the form of any combination of firmware and software. The control module 254 is connected to one or more actuation systems such as spectral feature actuation systems 255_1 to 255_n. Each of the actuation systems 255_1 to 255_n may include one or more actuators that are connected to respective optical features 256_1 to 256_n of an optical system 257. The optical features 256_1 to 256_n are configured to adjust particular characteristics of the generated light beam 260 to thereby adjust the spectral features of the light beam 260. The control module 254 receives a control signal from the control system 250, the control signal including specific commands to operate or control one or more of the actuation systems 255_1 to 255_n. The actuation systems 255_1 to 255_n can be selected and designed to work together, that is, in tandem, or the actuation system 255_1 to 255_n may be configured to work individually. Moreover, each actuation system 255_1 to 255_n may be optimized to respond to a particular class of disturbances.

Each of the actuators of the actuation systems 255_1 to 255_n may be an EAE for moving or controlling the respective optical features 256_1 to 256_n of the optical system 257. The actuators receive energy from the control module 254 and convert that energy into some kind of motion imparted to the optical features 256_1 to 256_n of the optical system 257.

Each optical feature 256_1 to 256_n is optically coupled to the light beam 260 produced by the optical source 105. The optical system 257 may be implemented as an LNM 216c such as that shown in FIG. 2C. The line narrowing module includes as the optical features 256_1 to 256_n dispersive optical elements such as a reflective grating 291 and refractive optical elements such as prisms 292, 293, 294, and 295. One or more of the prisms 292, 293, 294, and 295 may be rotatable. An example of this line narrowing module can be found in U.S. Pat. No. 8,144,739, titled “System Method and Apparatus for Selecting and Controlling Light Source Bandwidth”, issued Mar. 27, 2012 (the '739 patent). In the '739 patent, a line narrowing module is described that includes a beam expander (including the one or more prisms 292, 293, 294, and 295) and a dispersive element such as the grating 291.

All patent applications, patents, and printed publications cited herein are incorporated herein by reference in their entireties, except for any definitions, subject matter disclaimers or disavowals, and except to the extent that the incorporated material is inconsistent with the express disclosure herein, in which case the language in this disclosure controls.

The respective actuation systems for the optical features such as one or more of the prisms 292, 293, 294, and 295 are represented in FIG. 2C by EAEs 292a, 293a, 294a, and 295a, respectively. A mirror may also be present and rotated to change the angle of incidence of the light beam on the grating 291 and so the primary wavelength of the emitted light. The common element is that there is an EAE that causes the motion under the command of a voltage command signal. Thus, in general, the line narrowing module includes one or more optical elements that are rotated to change the primary wavelength of the light leaving the module. These EAEs must be able to move the optical elements very rapidly between two positions, usually two angular positions, in a process referred to as dithering.

Returning to FIG. 2A, the master oscillator 212 also includes a line center analysis module 220 that receives an output light beam from the output coupler 218 and a beam coupling optical system 222 that modifies the size or shape of the output light beam as needed to form the seed light beam 224. The line center analysis module 220 is a measurement system that may be used to measure or monitor the wavelength of the seed light beam 224. The line center analysis module 220 may be placed at other locations in the optical source 205, or it may be placed at the output of the optical source 205.

The power amplifier 230 includes a beam coupling optical system 232 that receives the seed light beam 224 from the master oscillator 212 and directs the seed light beam 224 through a discharge chamber 240, and to a beam turning optical element 248. The beam turning optical element 248 modifies or changes the direction of the seed light beam 224 so that it is sent back into the discharge chamber 240. The discharge chamber 240 includes a pair of elongated electrodes 241, a gain medium that is a gas mixture, and a fan for circulating the gas mixture between the electrodes 241.

The output light beam 260 is directed through a bandwidth analysis module 262, where various parameters (such as the bandwidth or the wavelength) of the beam 260 may be measured. The output light beam 260 may also be directed through a beam preparation system 263. The beam preparation system 263 may include, for example, a pulse stretcher, where each of the pulses of the output light beam 260 is stretched in time, for example, in an optical delay unit, to adjust for performance properties of the light beam that impinges on the lithography exposure apparatus 169. The beam preparation system 263 also may include other components that are able to act upon the beam 260 such as, for example, reflective and/or refractive optical elements (such as, for example, lenses and mirrors), filters, and optical apertures (including automated shutters).

The photolithography system 200 also includes the control system 250. In the implementation shown in FIG. 2A, the control system 250 is connected to various components of the optical source 205. For example, the control system 250 may control when the optical source 205 emits a pulse of light or a burst of light pulses that includes one or more pulses of light by sending one or more trigger signals to the optical source 205. The control system 250 is also connected to the lithography exposure apparatus 169. Thus, the control system 250 also may control the various aspects of the lithography exposure apparatus 169. For example, the control system 250 may control the exposure of the wafer 170 and thus may be used to control how electronic features are printed on the wafer 170. In some implementations, the control system 250 may control the scanning of the wafer 170 by controlling the motion of the slit 176 in the x-y plane (FIG. 1B). Moreover, the control system 250 may exchange data with the metrology system 172 and/or the optical system 175.

The lithography exposure apparatus 169 also may include, for example, temperature control devices (such as air conditioning devices and/or heating devices), and/or power supplies for the various electrical components. The control system 250 also may control these components. In some implementations, the control system 250 is implemented to include more than one sub-control system, with at least one sub-control system (a lithography controller) dedicated to controlling aspects of the lithography exposure apparatus 169. In these implementations, the control system 250 may be used to control aspects of the lithography exposure apparatus 169 instead of, or in addition to, using the lithography controller.

The control system 250 includes an electronic processor 251, an electronic storage 252, and an I/O interface 253. The electronic processor 251 includes one or more processors suitable for the execution of a computer program such as a general or special purpose microprocessor, and any one or more processors of any kind of digital computer. Generally, an electronic processor receives instructions and data from a read-only memory, a random access memory, or both. The electronic processor 251 may be any type of electronic processor.

The electronic storage 252 may be volatile memory, such as RAM, or non-volatile memory. In some implementations, the electronic storage 252 includes non-volatile and volatile portions or components. The electronic storage 252 may store data and information that is used in the operation of the control system 250, components of the control system 250, and/or systems controlled by the control system 250. The information may be stored in, for example, a look-up table or a database. For example, the electronic storage 252 may store data that indicates values of various properties of the beam 260 under different operating conditions and performance scenarios.

Moreover, the electronic storage 252 may store various recipes or process programs 259 that dictate parameters of the light beam 260 during use. For example, the electronic storage 252 may store a recipe that indicates the wavelength of each pulse in the light beam 260 for a particular exposure pass. The recipe may indicate different wavelengths for different exposure passes. The wavelength controlling techniques discussed below may be applied on a pulse-by-pulse basis. In other words, the wavelength content may be controlled for each individual pulse in an exposure pass to facilitate formation of the aerial images at the desired locations along the z axis.

The electronic storage 252 also may store instructions, perhaps as a computer program, that, when executed, cause the processor 251 to communicate with components in the control system 250, the optical system 205, and/or the lithography exposure apparatus 169.

The I/O interface 253 is any kind of electronic interface that allows the control system 250 to receive and/or provide data and signals with an operator, the optical system 205, the lithography exposure apparatus 169, any component or system within the optical system 205 and/or the lithography exposure apparatus 169, and/or an automated process running on another electronic device. For example, the I/O interface 253 may include one or more of a visual display, a keyboard, and a communications interface.

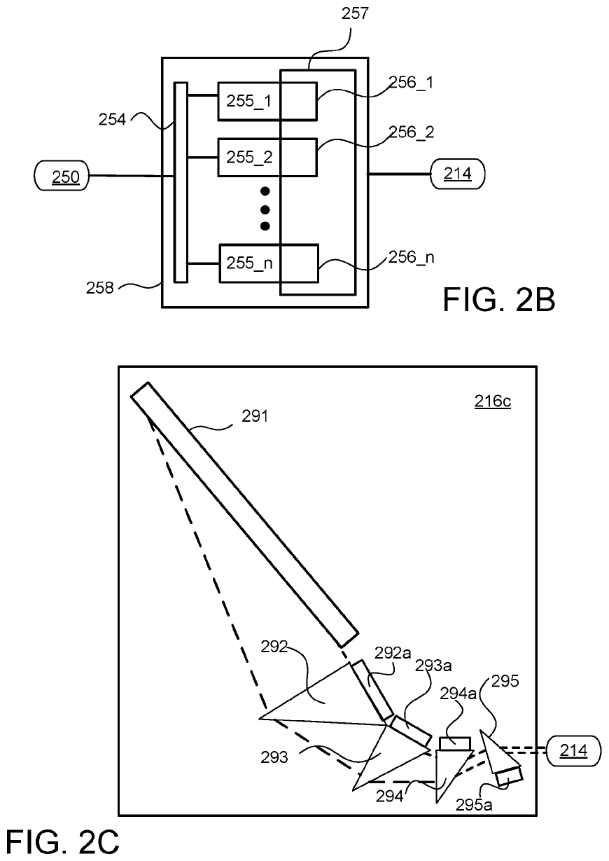

The light beam 260 (and the light beam 160) are pulsed light beams and may include one or more bursts of pulses that are separated from each other in time. Each burst may include one or more pulses of light. In some implementations, a burst includes hundreds of pulses, for example, 100-400 pulses. FIGS. 3A-3C provide an overview of the production of pulses and bursts in the optical source 205. FIG. 3A shows an amplitude of a wafer exposure signal 300 as a function of time, FIG. 3B shows an amplitude of a gate signal 315 as a function of time, and FIG. 3C shows an amplitude of a trigger signal 330 as a function of time.

The control system 250 may be configured to send the wafer exposure signal 300 to the optical source 205 to control the optical source 205 to produce the light beam 260. In the example shown in FIG. 3A, the wafer exposure signal 300 has a high value 305 (for example, logical 1) for a period of time 307 during which the optical source 205 produces bursts of pulses of light. The wafer exposure signal 300 otherwise has a low value 310 (for example, logical 0) when the wafer 170 is not being exposed.

Referring to FIG. 3B, the control system 250 also controls the duration and frequency of the bursts of pulses by sending a gate signal 315 to the optical source 205. The gate signal 315 has a high value 320 (for example, logical 1) during a burst of pulses and a low value 325 (for example, logical 0) during the time between successive bursts. In the example shown, the duration of time at which the gate signal 315 has the high value is also the duration of a burst 316. The bursts are separated in time by an inter-burst time interval. During the inter-burst time interval, the lithography exposure apparatus 169 may position the next die on the wafer 170 for exposure.

Referring to FIG. 3C, the control system 250 also controls the repetition rate of the pulses within each burst with a trigger signal 330. The trigger signal 330 includes triggers 340 that are provided to the optical source 205 to cause the optical source 205 to produce pulses of light. The control system 250 may send a trigger 340 to the source 205 each time a pulse is to be produced. Thus, the repetition rate of the pulses produced by the optical source 205 (the time between two successive pulses), or other timing of the pulses, may be set by the trigger signal 330.

As discussed above, when the gain medium 219 is pumped by applying voltage to the electrodes 217, the gain medium 219 emits light. When voltage is applied to the electrodes 217 in pulses, the light emitted from the medium 219 is also pulsed. Thus, the repetition rate of the pulsed light beam 260 is determined by the rate at which voltage is applied to the electrodes 217, with each application of voltage producing a pulse of light. The pulse of light propagates through the gain medium 219 and exits the chamber 214 through the output coupler 218. Thus, a train of pulses is created by periodic, repeated application of voltage to the electrodes 217. The trigger signal 330, for example, may be used to control the application of voltage to the electrodes 217 and the repetition rate of the pulses, which may range between about 500 and 6,000 Hz for most applications. In some implementations, the repetition rate may be greater than 6,000 Hz, and may be, for example, 12,000 Hz or greater.

The signals from the control system 250 may also be used to control the electrodes 217, 241 within the master oscillator 212 and the power amplifier 230, respectively, for controlling the respective pulse energies of the master oscillator 212 and the power amplifier 230, and thus, the energy of the light beam 260. There may be a delay between the signal provided to the electrodes 217 and the signal provided to the electrodes 241. The amount of delay may influence properties of the beam 260, such as the amount of coherence in the pulsed light beam 260.

The pulsed light beam 260 may have an average output power in the range of tens of watts, for example, from about 50 W to about 130 W. The irradiance (that is, the average power per unit area) of the light beam 260 at the output may range from 60 W/cm² to 80 W/cm².

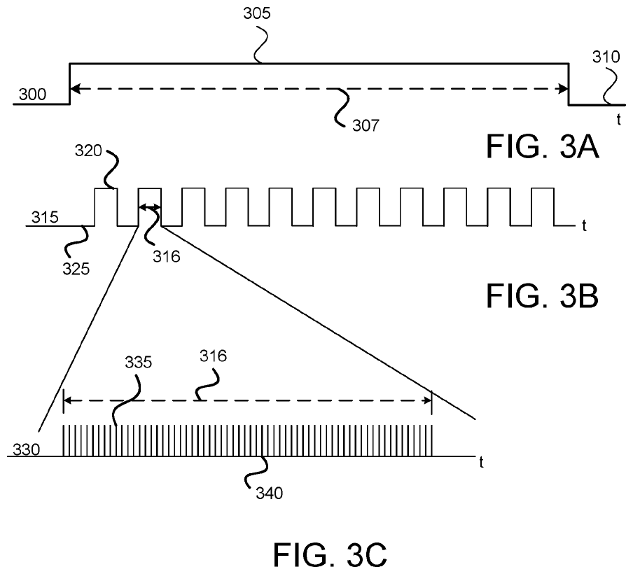

Referring also to FIG. 4, the wafer 170 is irradiated by the light beam 260. The lithography exposure apparatus 169 includes the optical system 175 (FIGS. 1A and 1B). In the example of FIG. 4, the optical system 175 (other parts not shown in FIG. 4) includes an illuminator system 429, which includes an objective arrangement 432. The objective arrangement 432 includes the projection lens 177 (FIG. 1B) and enables the image transfer to occur from the mask 174 to the photoresist on the wafer 170. The illuminator system 429 adjusts the range of angles for the light beam 260 impinging on the mask 174. The illuminator system 429 also may homogenize (make uniform) the intensity distribution of the light beam 260 in the x-y plane across the mask 174.

In some implementations, an immersion medium may be supplied to cover the wafer 170. The immersion medium may be a liquid (such as water) for liquid immersion lithography. In other implementations in which the lithography is a dry system, the immersion medium may be a gas such as dry nitrogen, dry air, or clean air. In other implementations, the wafer 170 may be exposed within a pressure-controlled environment (such as a vacuum or partial vacuum).

A plurality of N pulses of the light beam 260 illuminates the same area of the wafer 170. N may be any integer number greater than one. The number of pulses N of the light beam 110 that illuminate the same area may be referred to as an exposure window or exposure pass 400. The size of the window 400 may be controlled by the slit 176. For example, the slit 176 may include a plurality of blades that are movable such that the blades form an aperture that is open in one configuration and closed in another configuration. By arranging the blades of the slit 176 to form an aperture of a particular size, the size of the window 400 also may be controlled.

The N pulses also determine an illumination dose for the exposure pass. The illumination dose is the amount of optical energy that is delivered to the wafer during the exposure pass. Thus, properties of the N pulses, such as the optical energy in each pulse, determine the illumination dose. Moreover, and as discussed in greater detail below, the N pulses also may be used to determine the amount of light in each of the aerial images 173a, 173b (FIG. 1C). In particular, a recipe may specify that of the N pulses, a certain number of pulses have a first primary wavelength that forms the aerial image 173a and a certain number of pulses have a second primary wavelength that forms the aerial image 173b. These pulses, which will have wavelengths that differ from each other, may be interspersed, for example, pulse-to-pulse or in some other manner, i.e., in alternating groups of pulses.

Additionally, the slit 176 and/or the mask 174 may move in a scanning direction in the x-y plane such that only a portion of the wafer 170 is exposed at a given time or during a particular exposure scan (or exposure pass). The size of the area on the wafer 170 exposed by the light beam 160 is determined by the distance between the blades in the non-scanning direction and by the length (distance) of the scan in the scanning direction. In some implementations, the value of N is in the tens, for example, each point on the wafer may receive light from 10-100 consecutive pulses during the scanning of the slit relative to that point. In other implementations, the value of N is greater than 100 pulses, for example, from 100-500 pulses. An exposure field 479 of the wafer 170 is the physical area of the wafer 170 that is exposed in one scan of an exposure slit or window within the lithography exposure apparatus 169.

The wafer stage 171, the mask 174, and the objective arrangement 432 are fixed to associated actuation systems to thereby form a scanning arrangement. In the scanning arrangement, one or more of the mask 174, the objective arrangement 432, and the wafer 170 (via the stage 171) may move relative to each other in the x-y plane. However, aside from incidental relative operational motion between the wafer stage 171, the mask 174, and the objective arrangement 432, these elements are not moved relative to each other along the z axis during an exposure pass.

Referring again to FIG. 2A, typically, tuning of the wavelength of the beam 224 and, hence, the light beam 260 takes place in the LNM 216. A typical technique used for line narrowing and tuning of lasers is to provide a window at the back of the laser's discharge cavity through which a portion of the laser beam passes into the LNM 216. There, the portion of the beam is expanded with a prism beam expander and directed to a grating which reflects a narrow selected portion of the laser's broader spectrum back into the discharge chamber where it is amplified as described in connection with LNM 216c in FIG. 2C. The laser is typically tuned by changing the angle at which the beam illuminates the grating 291 using an actuator such as, for example, a piezoelectric actuator.

In some embodiments, the plurality of prisms 292-295 may be used to adjust the final incident angle, and consequently, the wavelength selected. For example, prism 292 may have more control over the final incident angle than the prism 293. That is, in some embodiments, the controller 250 uses prisms 292, 293 in a dual-stage configuration, with prism 292 being used for large jumps and to desaturate prism 293, which is used for finer changes to the final incident angle. Controlling prisms 292, 293 is of particular importance for MFI operations, which require more than regulation around a setpoint, and instead, require precise tracking of a sinusoid at Nyquist frequency in addition to precise control of the center point of the sinusoid (i.e., the central wavelength). There are processes for controlling the central wavelength for imaging operations, such as MFI operations.

Multifocal imaging operations may include a two-color mode. In the two-color mode, a wavelength target may alternate between two known setpoints within a burst (e.g., every pulse, pulse-to-pulse), and an electro-actuable component which may be implemented as a piezoelectric transducer (PZT) may be used to track, i.e. adjust the wavelength towards, the fast-changing wavelength target. As set forth above, for some applications it is beneficial to be able to generate one or more pulses having one wavelength and then be able to switch to generating one or more pulses having a different wavelength.

In some implementations, MFI operations provide for moving an actuator controlling movement of prism 293 during a burst. That is, the processes provide for an intra-burst solution for addressing a change to the center wavelength. A dynamic model of the actuator may be used to compute an optimal control waveform for actuating the actuator to minimize the difference between actual wavelength and wavelength targets.

In some embodiments, a dither waveform (or sequence) can be combined with an offset for moving an actuator for prism 293. For example, the dither waveform may be an applied form of noise used to randomize quantization. The offset can be updated at an end-of-burst (EOB) and/or at a set pulse interval. In some embodiments, the EOB update can move the actuator for prism 293 to zero out the estimated center wavelength drift obtained by averaging the wavelength measurements of the entire burst. In some embodiments, the interval updates can be based on an estimation process.

The optimal control waveform can be computed using any one of several methods. For example, the optimal control waveform may be computed using dynamic programming. This method is well adapted for dealing with complex models that contain nonlinear dynamics. If an actuator model is adopted that has strong nonlinear dynamics, then dynamic programming may be used to generate the optimal control signal for given wavelength targets. Dynamic programming does, however, present the challenge that it requires significant computational resources which may not be implementable in real-time. To overcome this a data storage device such as a pre-populated look-up-table or a pre-programmed field programmable gate array (FPGA) may be used which contains optimal control parameters for at least some of the different repetition rates at which the source may be operated.

As another example, the optimal control waveform may be determined using model inversion feedforward control. This method relies on an actuator dynamic model to construct a digital filter that inverts the actuator dynamic. By passing the desired waveform for the desired actuator trajectory through this filter, an optimal control waveform can be generated in real time to achieve zero steady state error tracking.

As another example, an optimal solution to achieve two separate wavelengths in a stable manner is accomplished using a learning algorithm to guarantee error convergence over several iterations of learning. Embodiments of the systems and methods disclosed herein can potentially achieve two separate wavelengths separated by 1000 femtometers (fm) with a separation error below 20 fm.

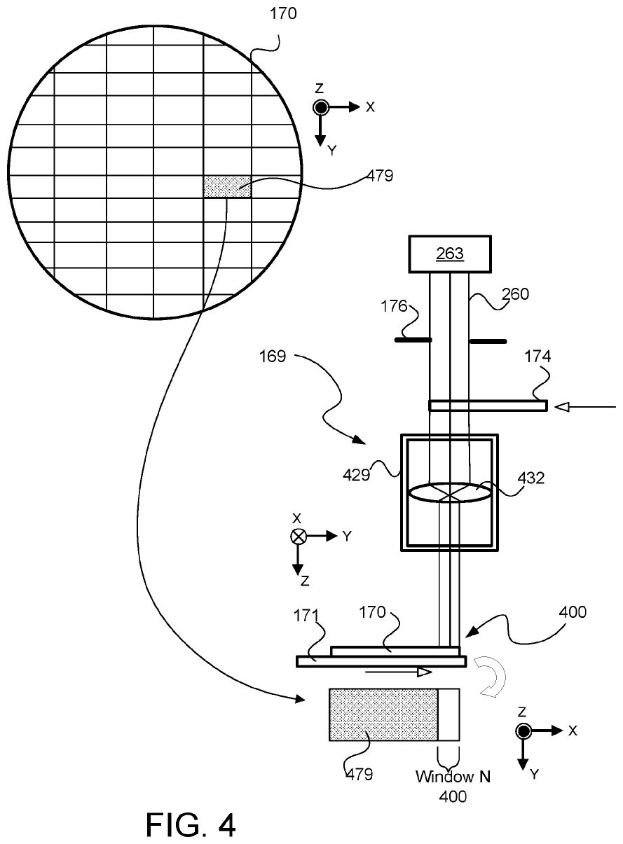

Referring to FIG. 5, an optical spectrum 601A of a pulse of light 600A is shown. The pulse of light 600A has non-zero intensity within a band of wavelengths. The band of wavelengths also may be referred to as the bandwidth of the pulse 600A.

The information shown in FIG. 5 is the instantaneous optical spectrum 601A (or emission spectrum) of the pulse 600A. The optical spectrum 601A contains information about how the optical energy or power of a pulse of the light beam 260 is distributed over different wavelengths (or frequencies). The optical spectrum 601A is depicted in the form of a diagram where the spectral intensity (not necessarily with an absolute calibration) is plotted as a function of the wavelength or optical frequency. The optical spectrum 601A may be referred to as the spectral shape or intensity spectrum of a pulse of the light beam 260. The pulse 600A has a primary wavelength 602A, which, in the example of FIG. 5, is the peak intensity. Although the discussion of the pulses of the light beam 260 and the aerial images formed by the pulses of the light beam 260 refers to the primary wavelengths of the pulses, the pulses include wavelengths other than the primary wavelength and the pulses have a finite bandwidth that may be characterized by a metric. For example, the full width of the spectrum 601A at a fraction (X) of the maximum peak intensity of the spectral shape (referred to as FWXM) may be used to characterize the light beam bandwidth. As another example, the width of the spectrum that contains a fraction (Y) of the integrated spectral intensity (referred to as EY) may be used to characterize the light beam bandwidth.

The pulse 600A is shown as an example of a pulse that may be in the light beam 260.

When the pulse 600A is used to expose a portion of the wafer 170, the light in the pulse forms an aerial image. The location of the aerial image in the z direction (FIGS. 1A-C) is determined by the value of the primary wavelength 602A. The various pulses in the light beam 260 may have different primary wavelengths. For example, to generate two aerial images during a single exposure pass, some of the pulses of the light beam 260 have one primary wavelength (a first primary wavelength) and the other pulses of the light beam 260 have another primary wavelength (a second primary wavelength). The first and second primary wavelengths are different wavelengths. The wavelength difference between the first and second primary wavelengths may be referred to as the spectral separation. Although the wavelengths of the various pulses in the light beam 260 may be different, the shape of the optical spectra of the pulses may be the same.

The light source 205 may dither or switch the primary wavelength between the first and second primary wavelengths on a burst-to-burst, pulse-to-pulse, or even an intrapulse basis. For the pulse-to-pulse case each pulse has a different primary wavelength than a pulse that immediately precedes or follows the pulse in time. In these implementations, assuming that all of the pulses in the light beam 260 have the same intensity, distributing the first and second primary wavelengths in this manner results in two aerial images at different locations in the z direction with the same intensity.

In some implementations, a certain portion (for example, 33%) of the pulses have a first primary wavelength, and the remainder (67% in this example) have a second primary wavelength. Here and elsewhere, “first” and “second” are used merely as differentiating labels, and not temporal order, unless the context suggests otherwise. In these implementations, assuming that all of the pulses in the light beam 260 have the same intensity, two aerial images are formed of different intensities. The aerial image formed by the pulses having the first primary wavelength has about half of the intensity of the aerial image formed by the pulses having the second primary wavelength. In this way, the dose provided to a particular location in the wafer 170 along the z axis may be controlled by controlling the portion of the N pulses that have the first primary wavelength and the portion of the N pulses that have the second primary wavelength.

The portion of pulses that are to have a particular primary wavelength for an exposure pass may be specified in the recipe file 259 that is stored in the electronic storage 252 (see FIG. 2A). The recipe file 259 specifies the ratio of the various primary wavelengths for an exposure pass. The recipe file 259 also may specify the ratio for other exposure passes, such that a different ratio may be used for other exposure passes and the aerial images may be adjusted or controlled on a field-by-field basis.

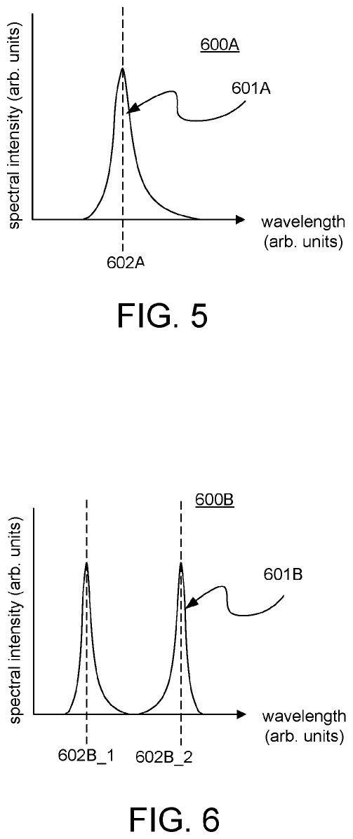

Referring to FIG. 6, an optical spectrum 601B of a pulse 600B is shown. The pulse 600B is another example of pulse of the light beam 260. The optical spectrum 601B of the pulse 600B has a different shape than the optical spectrum 601A. In particular, the optical spectrum 601B has two peaks that correspond to two primary wavelengths 602B_1 and 602B_2 of the pulse 600B. The pulse 600B is part of the light beam 260. When the pulse 600B is used to expose a portion of the wafer 120, the light in the pulse forms two aerial images at different locations along the z axis on the wafer. The locations of the aerial images are determined by the wavelengths of the primary wavelengths 602B_1 and 602B_2. Thus, one goal of a control system according to an embodiment is to control the primary wavelengths toward respective target values, i.e., to cause each primary wavelength to converge to its target value and, hence, for the separation amount to achieve a target amount.

The pulses shown in FIGS. 5 and 6 may be formed by any hardware capable of forming such pulses. For example, a pulse train of pulses such as the pulse 600A may be formed using a line narrowing module similar to the LNM 216C of FIG. 2C. As mentioned, the wavelength of the light diffracted by the grating 291 depends on the angle of the light that is incident on the grating. A mechanism to change the angle of incidence of light that interacts with the grating 291 may be used with such a line narrowing module to create a pulse train with N pulses for an exposure pass, where at least one of the N pulses has a primary wavelength that is different from the primary wavelength of another pulse of the N pulses. For example, one of the prisms 292, 293, 294, and 295 may be rotated to change the angle of light that is incident on the grating 291 on a pulse-by-pulse basis. In some implementations, the line narrowing module includes a mirror that is in the path of the beam 260 and is movable to change the angle of light that is incident on the grating 291. An example of such an implementation is discussed, for example, in U.S. Pat. No. 6,192,064, titled “Narrow Band Laser with Fine Wavelength Control”, issued on Feb. 20, 2001.

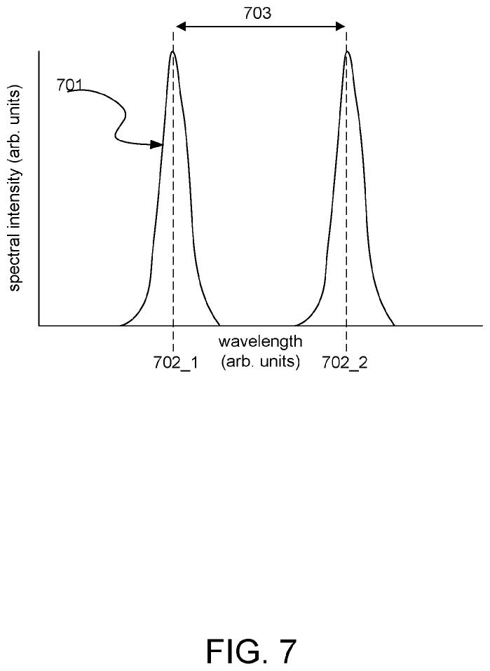

Referring again to FIG. 4, a set of pulses of light is passed through the mask 174 toward the wafer 170 during a single exposure pass. As discussed above, N pulses of light may be provided to the wafer 170 during the exposure pass. The N pulses of light may be consecutive pulses of light in the beam 260. The exposed portion of the wafer 170 sees an average of the optical spectrum of each of the N pulses over the exposure pass. Thus, if a portion of the N pulses have a first primary wavelength and the remaining portion of the N pulses have a second primary wavelength, the average optical spectrum at the wafer 170 will be an optical spectrum that includes a peak at the first primary wavelength and a peak at the second primary wavelength. Similarly, if all or some of the individual pulses of the N pulses have more than one primary wavelength, those primary wavelengths may form peaks in the average optical spectrum. FIG. 7 shows an example of an average optical spectrum 701 at the wafer 170. The averaged optical spectrum 701 includes a first primary wavelength 702_1 and a second primary wavelength 702_2. In the example of FIG. 7, the first primary wavelength 702_1 and the second primary wavelength 702_2 are separated by a spectral separation 703. The spectral separation 703 is such that the first primary wavelength 702_1 and the second primary wavelength 702_2 are distinct, and the average optical spectrum 701 includes a spectral region of little to no intensity between the wavelengths 702_1 and 702_2.

As mentioned, the technical challenge presented by attempting to base a control signal on feed-forward control and a standard mathematical model is that the behavior of the PZT in the LNM exhibits a lack of predictability at and near the PZT resonance frequency and harmonics (integral multiples) of that frequency. The PZT resonance frequency may be, for example, about 2100 Hz. This means that the PZT behavior is unpredictable at or near that repetition rate and also at or near a repetition rate of 4200 Hz, and so on. The practical effect of this is that a user is constrained to avoid frequencies at or near these repetition rates, n*fᵣ±Δf, where n is a positive integer, fᵣ is the resonance frequency of the PZT, and ±Δf is the range of repetition rates around the resonance or harmonic in which the PZT behavior is unpredictable, typically within 10% of the resonance frequency of the PZT or a harmonic of the resonance frequency of the PZT. Otherwise, peak separation may not settle down until late in a burst. Herein, the term “critical range” refers to repetition rates within 10% of the resonance frequency of the PZT or a harmonic of the resonance frequency of the PZT.

According to an aspect of an embodiment, the uncertainty of the PZT parameters is addressed using model reference adaptive control (MRAC) to quickly achieve a desired peak separation even when the laser fires, for example, in the range around and including 2*fᵣ Hz. The unknown performance of the PZT near resonance is treated as parameter uncertainty in a reference model of the PZT. The control system does not depend on an accurate PZT calibration result because it is able to adapt the control parameters in response to resonance uncertainty. Such a control system also permits real-time feedback control which is better able to manage any external disturbance. The use of such a control system makes it possible for peak separation to achieve its desired value early in a burst, e.g., by the third pulse. As a practical matter, this removes the constraint against operating at repetition rates that are related to the PZT resonant frequency. In particular, this provides sufficiently reliable performance at 2*fᵣ to permit operation in an MFI mode at such a repetition rate.

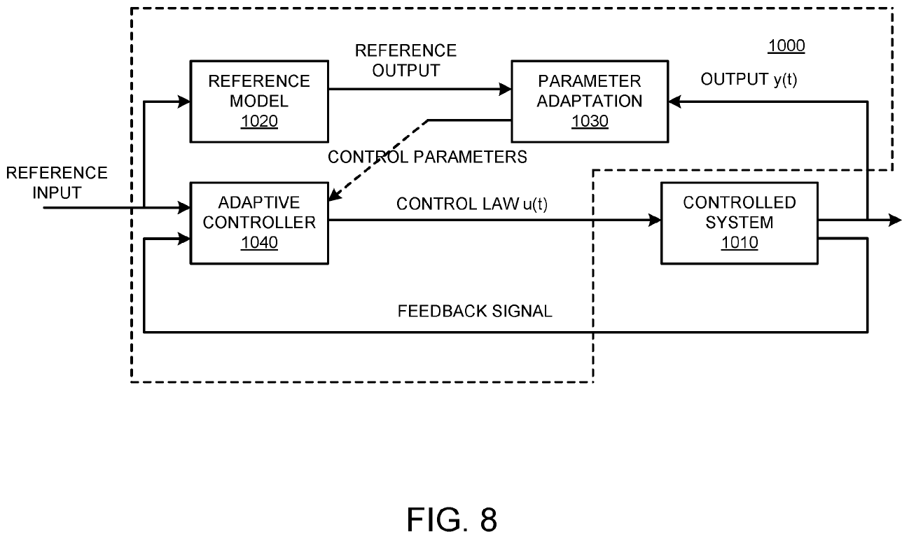

As shown in FIG. 8, an MRAC system 1000 is configured to control the operation of a controlled system (e.g., actuator) 1010. The output of the controlled system 1010 is supplied as a feedback signal to the adaptive controller 1040. Because the behavior of the controlled system 1010 lacks predictability during operation in certain ranges of repetition rates, however, according to an aspect of an embodiment, the embodiment of the MRAC system 1000 depicted includes a reference model 1020, a parameter adaptation module 1030, and an adaptive controller 1040.

A reference input is applied to the reference model 1020 and the adaptive controller 1040. The adaptive controller 1040 develops a control law signal u(t) based on the reference input. The reference model 1020 produces a reference output in response to the reference input. The controlled system 1010 (e.g., line narrowing module with one or more actuators) produces an output in response to the signal u(t) and a feedback signal. The output y(t) is provided to the parameter adaptation module 1030. The parameter adaptation module 1030 determines a difference between the reference output and the output y(t) as a tracking error and supplies adapted operational parameters to the adaptive controller 1040. The adaptive controller 1040 develops the control law u(t) based on the adapted operational parameters. The parameter adaptation module 1030 automatically adjusts controller parameters so that the behavior of the output y(t) of the closed loop controlled system 1010 closely follows that of the reference model 1020. In other words, as the control parameters are adjusted, the tracking error converges such that the behavior of the controlled system 1010 tracks the behavior of the reference model 1020.

In this example, the controlled system 1010 is an actuator that is regulated to control the peak separation of the two wavelengths being generated by the laser. The parameter adaptation module 1030 determines a difference in peak separation between the reference output and the output y(t) as a tracking error and supplies adapted operational parameters to adaptive controller 1040. As described above, this peak separation ideally settles to a stable value quickly at the beginning of a burst. Also as described above, it is difficult to achieve such a rapid onset of stability when the laser is being operated at a repetition rate at or near the resonance of the actuator (e.g., PZT actuator) and harmonics of that resonance. Using the described system, however, a stable peak separation can be achieved quickly after the beginning of a burst even at repetition rates at or near these resonant frequencies and their harmonics.

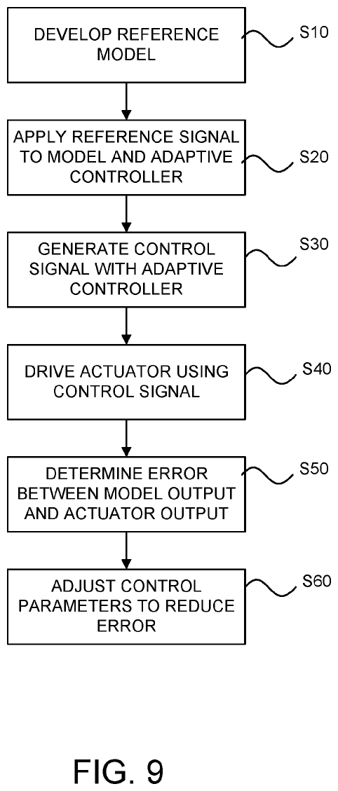

FIG. 9 is a flow chart which describes an adaptive model reference adaptive control system according to an aspect of an embodiment. In a step S10, a reference model is developed. In a step S20, a reference signal is applied to the reference model and to an adaptive controller. At a step S30, the adaptive controller generates a control signal based on the reference signal. As a practical matter, it is advantageous to have the parameters of the operational control signal as close to anticipated values as practical. In a step S40, the controlled actuator is driven using the control signal. In a step S50, an error or difference between the output of the reference model and of the controlled actuator is determined. In a step S60, the operational control parameters are adjusted to reduce the error or difference signal between the output of the reference model and the output of the controlled actuator. This manner, the error converges and the behavior of the controlled actuator is made to conform to the behavior of the reference model.

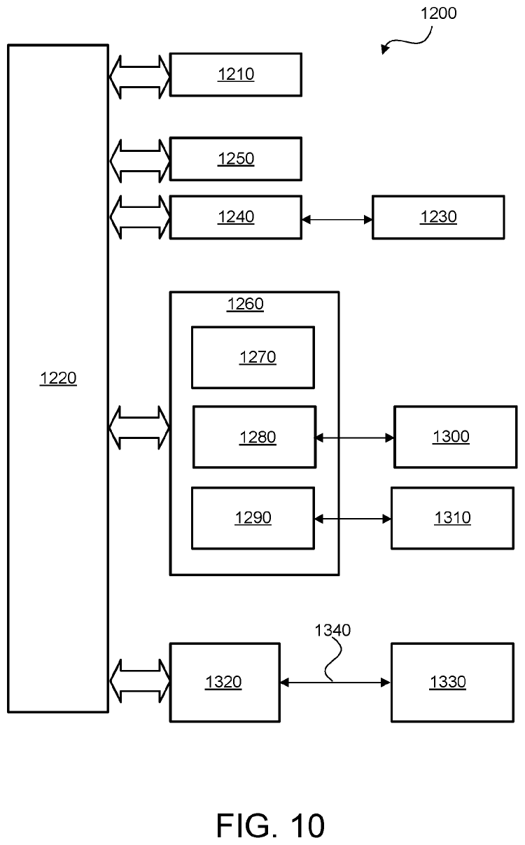

As shown in FIG. 10, various embodiments and components therein can be implemented, for example, using one or more well-known computer systems, such as, for example, the example embodiments, systems, and/or devices shown in the figures or otherwise discussed. Computer system 1200 can be any well-known computer capable of performing the functions described herein.

Computer system 1200 includes one or more processors (also called central processing units, or CPUs), such as a processor 1210. Processor 1210 is connected to a communication infrastructure or bus 1220.

One or more processors 1210 may each be a graphics processing unit (GPU). In an embodiment, a GPU is a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 1200 also includes user input/output device(s) 1230, such as monitors, keyboards, pointing devices, etc., that communicate with communication infrastructure 1220 through user input/output interface(s) 1240.

Computer system 1200 also includes a main or primary memory 1250, such as random access memory (RAM). Main memory 1250 may include one or more levels of cache. Main memory 1250 has stored therein control logic (i.e., computer software) and/or data.

Computer system 1200 may also include one or more secondary storage devices or memory 1260. Secondary memory 1260 may include, for example, a hard disk drive 1280 and/or a removable storage device or drive 1290. Removable storage drive 1290 may be a floppy disk drive, a magnetic tape drive, a compact disk drive, an optical storage device, tape backup device, and/or any other storage device/drive.

Removable storage drive 1290 may interact with a removable storage unit 1300. Removable storage unit 1300 includes a computer usable or readable storage device having stored thereon computer software (control logic) and/or data. Removable storage unit 1300 may be a floppy disk, magnetic tape, compact disk, DVD, optical storage disk, and/any other computer data storage device. Removable storage drive 1290 reads from and/or writes to removable storage unit 1300 in a well-known manner.

According to an example embodiment, secondary memory 1260 may include other means, instrumentalities, or other approaches for allowing computer programs and/or other instructions and/or data to be accessed by computer system 1200. Such means, instrumentalities or other approaches may include, for example, a removable storage unit 1310. Examples of the removable storage unit 1310 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface.

Computer system 1200 may further include a communication or network interface 1320. Communication interface 1320 enables computer system 1200 to communicate and interact with any combination of remote devices, remote networks, remote entities, etc. (individually and collectively referenced by reference number 1330). For example, communication interface 1320 may allow computer system 1200 to communicate with remote devices 1330 over communications path 1340, which may be wired and/or wireless, and which may include any combination of LANs, WANs, the Internet, etc. Control logic and/or data may be transmitted to and from computer system 1200 via communications path 1340.

In an embodiment, a non-transitory, tangible apparatus or article of manufacture comprising a non-transitory, tangible computer useable or readable medium having control logic (software) stored thereon is also referred to herein as a computer program product or program storage device. This includes, but is not limited to, computer system 1200, main memory 1008, secondary memory 1010, and removable storage units 1018 and 1022, as well as tangible articles of manufacture embodying any combination of the foregoing. Such control logic, when executed by one or more data processing devices (such as computer system 1200), causes such data processing devices to operate as described herein.

Based on the teachings contained in this disclosure, it will be apparent to persons skilled in the relevant art(s) how to make and use embodiments of this disclosure using data processing devices, computer systems and/or computer architectures other than that shown in FIG. 10. In particular, embodiments may operate with software, hardware, and/or operating system implementations other than those described herein.

Although specific reference may have been made above to the use of embodiments in the context of optical lithography, it will be appreciated that embodiments may be used in other applications, for example imprint lithography, and where the context allows, is not limited to optical lithography.

It is to be understood that the phraseology or terminology herein is for the purpose of description and not of limitation, such that the terminology or phraseology of the present specification is to be interpreted by those skilled in relevant art(s) in light of the teachings herein.

It is to be appreciated that the Detailed Description section, and not the Summary and Abstract sections, is intended to be used to interpret the claims. The Summary and Abstract sections may set forth one or more but not all exemplary embodiments as contemplated by the inventor(s), and thus, are not intended to limit the embodiments and the appended claims in any way.

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the embodiments that others can, by applying knowledge within the skill of the art, readily modify and/or adapt for various applications such specific embodiments, without undue experimentation, without departing from the general concept of the embodiments. Therefore, such adaptations and modifications are intended to be within the meaning and range of equivalents of the disclosed embodiments, based on the teaching and guidance presented herein.

The breadth and scope of the embodiments should not be limited by any of the above-described exemplary embodiments but should be defined only in accordance with the following claims and their equivalents.

The embodiments can be further described using the following clauses.
1. A laser system comprising:
a source of laser radiation, the laser radiation being fired in one or more bursts, each burst being made up of a plurality of pulses;
a wavelength controller arranged to receive the pulses and to control a primary wavelength of some of the pulses toward a first value and to control a primary wavelength of others of the pulses toward a second value different from the first value by a target primary wavelength separation amount, the wavelength controller including at least one actuator operating in response to a control signal to effect wavelength control of the pulses; and
a model reference adaptive control system adapted to generate the control signal based at least in part on a measured primary wavelength separation amount, to cause the wavelength controller to achieve the target primary wavelength separation amount.
2. The laser system of clause 1 wherein the source of laser radiation is an excimer laser.
3. The laser system of clause 1 wherein the actuator comprises a piezoelectric transducer.
4. The laser system of clause 1 wherein the wavelength controller is a line narrowing module.
5. The laser system of clause 1 wherein the wavelength controller is a line narrowing module including an optical element mechanically coupled to the at least one actuator.
6. The laser system of clause 5 wherein the at least one actuator comprises a piezoelectric transducer.
7. A multifocal imaging photolithography system generating first wavelength pulses of deep ultraviolet radiation having a first primary wavelength and second wavelength pulses of deep ultraviolet radiation having a second primary wavelength differing from the first primary wavelength by a primary separation amount, the multifocal imaging photolithography system comprising:
a wavelength controller arranged to receive input pulses of deep ultraviolet radiation and to control a primary wavelength of a first subset of the pulses to obtain the first wavelength pulses and to control a primary wavelength of a second subset of the input pulses to obtain the second wavelength pulses in response to a control signal; and
a model reference adaptive control system adapted to generate the control signal based at least in part on a measured primary separation of wavelengths of the first wavelength pulses and the second wavelength pulses to cause the wavelength controller to achieve and maintain a target primary separation amount.
8. The multifocal imaging photolithography system of clause 7 wherein the source of laser radiation is an excimer laser.
9. The multifocal imaging photolithography system of clause 7 wherein the wavelength controller comprises an electro-actuable component.
10. The multifocal imaging photolithography system of clause 7 wherein the wavelength controller is a line narrowing module.
11. The multifocal imaging photolithography system of clause 10 wherein the line narrowing module comprises an electro-actuable component.
12. The multifocal imaging photolithography system of clause 11 wherein the electro-actuable component comprises a piezoelectric transducer.
13. A system for controlling a wavelength of laser radiation being fired in one or more bursts, each burst being made up of a plurality of pulses, the system comprising:
a wavelength controller arranged to receive the pulses and to control a primary wavelength of some of the pulses towards a first value and to control a primary wavelength of others of the pulses towards a second value different from the first value by a target primary wavelength separation amount, the wavelength controller including at least one actuator operating in response to a control signal to effect wavelength control of the pulses; and
a model reference adaptive control system adapted to generate the control signal based at least in part on a measured primary separation amount to cause the wavelength controller to achieve the target primary separation amount.
14. The system of clause 13 wherein the actuator comprises a piezoelectric transducer.
15. The system of clause 13 wherein the wavelength controller is a line narrowing module.
16. The system of clause 13 wherein the wavelength controller is a line narrowing module including an optical element mechanically coupled to the actuator.
17. The system of clause 16 wherein the actuator comprises a piezoelectric transducer.
18. The system of clause 13 wherein each burst comprises the plurality of pulses fired at a repetition rate, and wherein the model reference adaptive control system is adapted to generate the control signal based at least in part on a measured primary wavelength separation amount to cause the wavelength controller to achieve the target primary separation amount even when the repetition rate is in a critical range at which operation of the electro-actuable component would otherwise be unstable.
19. The system of clause 18 wherein the critical range is +/−10% of a resonance frequency of the electro-actuable component or a harmonic of the resonance frequency of the electro-actuable component.
20. The system of clause 18 wherein the electro-actuable component comprises a piezoelectric transducer.
21. A method of controlling a multifocal imaging photolithography system to generate first wavelength pulses of radiation having a first primary wavelength and second wavelength pulses of radiation having a second primary wavelength differing from the first primary wavelength by a primary separation amount, the method comprising:
generating input pulses of laser radiation;
using a wavelength controller to control a primary wavelength of a first subset of the input pulses to obtain the first wavelength pulses and to control a primary wavelength of a second subset of the input pulses to obtain the second wavelength pulses in response to a control signal;
comparing a primary wavelength separation of the first wavelength pulses and the second wavelength pulses with a primary wavelength separation obtained from a reference model controlled by a reference signal to obtain an error signal; and
modifying one or more parameters of the control signal at least partially on the basis of the error signal to cause a response of the wavelength controller to the control signal to track a response of the reference model to the reference signal.
22. The method of clause 21 wherein generating input pulses of laser radiation is performed using an excimer laser.
23. The method of clause 22 wherein using a wavelength controller comprises using a line narrowing module.

The above described implementations and other implementations are within the scope of the following claims.

1. A laser system comprising:
a source of laser radiation, the laser radiation being fired in one or more bursts, each burst being made up of a plurality of pulses;
a wavelength controller arranged to receive the pulses and to control a primary wavelength of some of the pulses toward a first value and to control a primary wavelength of others of the pulses toward a second value different from the first value by a target primary wavelength separation amount, the wavelength controller including at least one actuator operating in response to a control signal to effect wavelength control of the pulses; and
a model reference adaptive control system adapted to generate the control signal based at least in part on a measured primary wavelength separation amount, to cause the wavelength controller to achieve the target primary wavelength separation amount.

2-6. (canceled)

7. A multifocal imaging photolithography system generating first wavelength pulses of deep ultraviolet radiation having a first primary wavelength and second wavelength pulses of deep ultraviolet radiation having a second primary wavelength differing from the first primary wavelength by a primary separation amount, the multifocal imaging photolithography system comprising:
a wavelength controller arranged to receive input pulses of deep ultraviolet radiation and to control a primary wavelength of a first subset of the pulses to obtain the first wavelength pulses and to control a primary wavelength of a second subset of the input pulses to obtain the second wavelength pulses in response to a control signal; and
a model reference adaptive control system adapted to generate the control signal based at least in part on a measured primary separation of wavelengths of the first wavelength pulses and the second wavelength pulses to cause the wavelength controller to achieve and maintain a target primary separation amount.

8. (canceled)

9. The multifocal imaging photolithography system of claim 7 wherein the wavelength controller comprises an electro-actuable component.

10. The multifocal imaging photolithography system of claim 7 wherein the wavelength controller is a line narrowing module.

11-12. (canceled)

13. A system for controlling a wavelength of laser radiation being fired in one or more bursts, each burst being made up of a plurality of pulses, the system comprising:
a wavelength controller arranged to receive the pulses and to control a primary wavelength of some of the pulses towards a first value and to control a primary wavelength of others of the pulses towards a second value different from the first value by a target primary wavelength separation amount, the wavelength controller including at least one actuator operating in response to a control signal to effect wavelength control of the pulses; and
a model reference adaptive control system adapted to generate the control signal based at least in part on a measured primary separation amount to cause the wavelength controller to achieve the target primary separation amount.

14. The system of claim 13 wherein the actuator comprises a piezoelectric transducer.

15. The system of claim 13 wherein the wavelength controller is a line narrowing module.

16-17. (canceled)

18. The system of claim 13 wherein each burst comprises the plurality of pulses fired at a repetition rate, and wherein the model reference adaptive control system is adapted to generate the control signal based at least in part on a measured primary wavelength separation amount to cause the wavelength controller to achieve the target primary separation amount even when the repetition rate is in a critical range at which operation of the electro-actuable component would otherwise be unstable.

19. The system of claim 18 wherein the critical range is +/−10% of a resonance frequency of the electro-actuable component or a harmonic of the resonance frequency of the electro-actuable component.

20. The system of claim 18 wherein the electro-actuable component comprises a piezoelectric transducer.

21. A method of controlling a multifocal imaging photolithography system to generate first wavelength pulses of radiation having a first primary wavelength and second wavelength pulses of radiation having a second primary wavelength differing from the first primary wavelength by a primary separation amount, the method comprising:
generating input pulses of laser radiation;
using a wavelength controller to control a primary wavelength of a first subset of the input pulses to obtain the first wavelength pulses and to control a primary wavelength of a second subset of the input pulses to obtain the second wavelength pulses in response to a control signal;
comparing a primary wavelength separation of the first wavelength pulses and the second wavelength pulses with a primary wavelength separation obtained from a reference model controlled by a reference signal to obtain an error signal; and
modifying one or more parameters of the control signal at least partially on the basis of the error signal to cause a response of the wavelength controller to the control signal to track a response of the reference model to the reference signal.

22. (canceled)

23. The method of claim 22 wherein using the wavelength controller comprises using an actuator.

24. The laser system of claim 1, wherein the model reference adaptive control system includes a reference model, an adaptive controller, and the reference model and the adaptive controller are configured to receive a same reference input in parallel.

25. The laser system of claim 24, wherein the model reference adaptive control system includes a parameter adaption module configured to generate at least one adapted operational parameter to the adaptive controller.

26. The laser system of claim 25, wherein the model reference adaptive control system includes a controlled system configured to receive a control law signal from the adaptive controller, and generate a feedback signal to the controller.

27. The laser system of claim 26, wherein, in response to the control law signal, the controlled system is configured to generate an output signal to the parameter adaption module, and wherein, in response to the reference input, the reference model is configured to generate a reference output to the parameter adaption module.

28. The laser system of claim 27, wherein, after receiving the output signal and the reference output, the parameter adaption module is configured to determine a difference between the output signal and the reference output as a tracking error and generate the at least one adapted operational parameter to the adaptive controller.

29. The multifocal imaging photolithography system of claim 9, wherein wavelength controller does not depend on a calibration result of the electro-actuable component.

30. The system of claim 13, wherein the model reference adaptive control system is configured to converge a tracking error in response to the measured primary separation amount to converge the primary wavelength of the some of the pulses towards the first value and to converge the primary wavelength of the other of the pulses towards the second value.

31. The method of claim 21, wherein generating the input pulses of laser radiation includes operating a repetition rate of a light source at a frequency around a resonance frequency of the actuator or harmonics of the resonance frequency of the actuator.
